(19) United States
(12) Patent Application Publication
(10) Pub. No.: US 2011/0115821 A1
(43) Pub. Date: May 19, 2011

(54) Control Method, Control Device and Electronic Device

(76) Inventors: Hao-Jan Huang, Hsinchu City (TW); Tzung-Yuan Lee, Taichung County (TW); Wing-Kai Tang, Hsinchu City (TW)

(21) Appl. No.: 12/687,109

(22) Filed: Jan. 13, 2010

(30) Foreign Application Priority Data
Nov. 13, 2009 (TW) 098138651

(51) Int. Cl. G09G 5/32; H03K 17/945; G06F 3/033; G09G 5/00

(52) U.S. Cl. 345/660; 327/517; 715/863; 345/156; 345/173

(57) ABSTRACT

A control method for an electronic device includes detecting a distance between an object and a reference point of the electronic device, and generating a control command for the electronic device according to the distance between the object and the reference point, in order to control the electronic device to perform a corresponding function.

### BACKGROUND OF THE INVENTION

1. Field of the Invention

The present invention relates to a control method, control device and electronic device, and more particularly, to a control method, control device and electronic device capable of providing intuitive control, to enhance operating fun and convenience.

2. Description of the Prior Art

A touch control display device has merits such as convenient operation, quick response and saving space, and provides a more intuitive and convenient control method, such that the touch control display device has become an important input interface and been widely used in a variety of consumer electronics products, e.g. personal digital assistants (PDAs), smart mobile communication devices, laptops and point of sale (POS) systems. Meanwhile, with the advance of touch control technique, a conventional single-point touch control method is evolved into a multiple-point touch control method, for realizing a more intuitive control method.

For example, please refer to FIG. 1A and FIG. 1B, which are schematic diagrams of operating a smart mobile communication device 10 via the multiple-point touch control method in the prior art. In FIG. 1A and FIG. 1B, a user uses two fingers (thumb and forefinger) to control the smart mobile communication device 10 to display a picture. When the user separates the thumb and the forefinger outwardly, the picture is magnified, as shown in FIG. 1A. On the contrary, when the user closes the thumb and the forefinger inwardly, the picture is minified, as shown in FIG. 1B.

Via the multiple-point touch control method, the user can use both the thumb and the forefinger to control the smart mobile communication device 10, which realizes the intuitive control, and further enhances operating fun. However, for a disabled user or some applications, the user may not be able to simultaneously click multiple touch points or make big moves, which limits the application range of the multiple-point touch control method.

### SUMMARY OF THE INVENTION

It is therefore an object of the present invention to provide a control method, control device and electronic device.

The present invention discloses a control method for an electronic device. The method includes detecting a distance between an object and a reference point of the electronic device, and generating a control command for the electronic device according to the distance between the object and the reference point, to control the electronic device to perform a corresponding function.

The present invention further discloses a control device for an electronic device. The control device includes a distance measuring unit, for detecting a distance between an object and a reference point of the electronic device, to generate a detection result, and a command generating unit, for generating a control command for the electronic device according to the detection result, to control the electronic device to perform a corresponding function.

The present invention further discloses an electronic device, capable of enhancing operating efficiency. The electronic device includes an operating circuit, a screen and a control device. The control device includes a distance measuring unit, for detecting a distance between an object and a reference point of the screen, to generate a detection result, and a command generating unit, for generating a control command for the operating circuit according to the detection result, to control the operating circuit to perform a corresponding function.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A and FIG. 1B are schematic diagrams of operating a smart mobile communication device via a multiple-point touch control method in the prior art.

FIG. 2 is a functional block diagram of a control device according to an embodiment of the present invention.

FIG. 3A and FIG. 3B are a front-view and a lateral-view diagrams of a smart mobile communication device according to an embodiment of the present invention.

FIG. 4A, FIG. 4B, FIG. 5A, and FIG. 5B are schematic diagrams of operating the smart mobile communication device shown in FIG. 3A.

FIG. 6 is a schematic diagram of the smart mobile communication device shown in FIG. 3A with three reference points.

FIG. 7 is a schematic diagram of a control process according to an embodiment of the present invention.

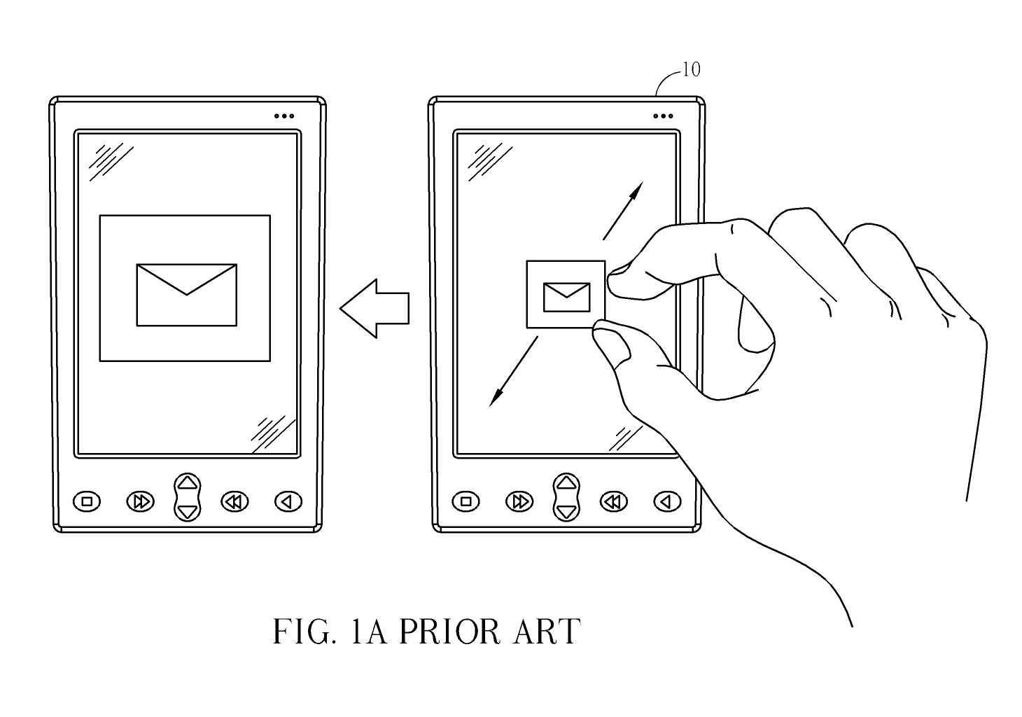

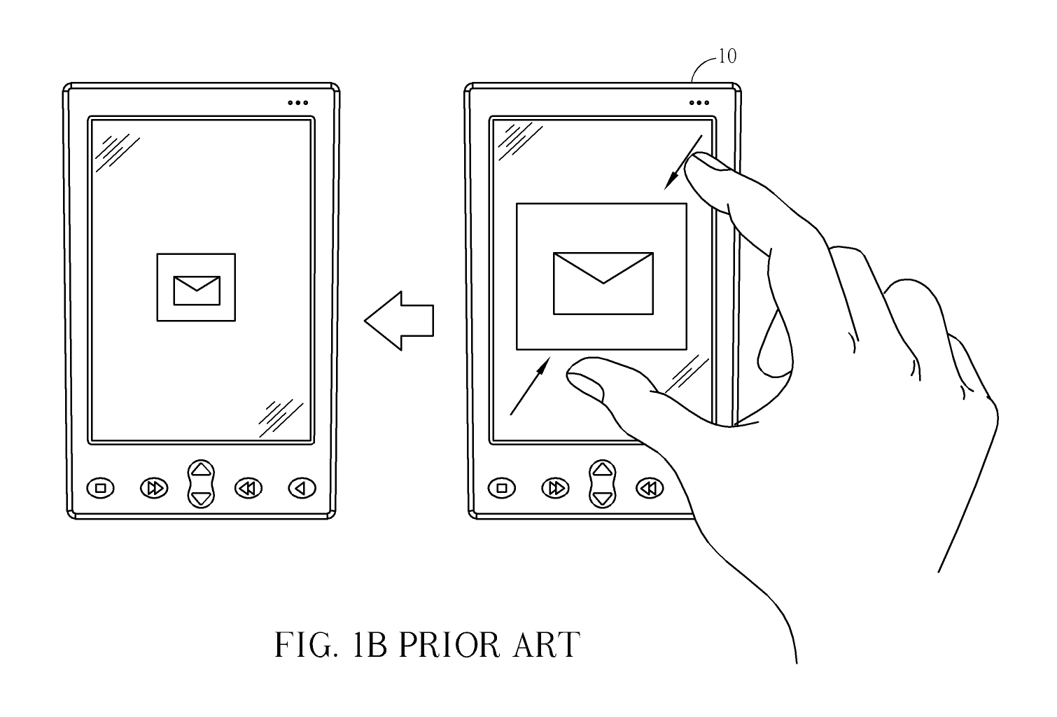

### DETAILED DESCRIPTION

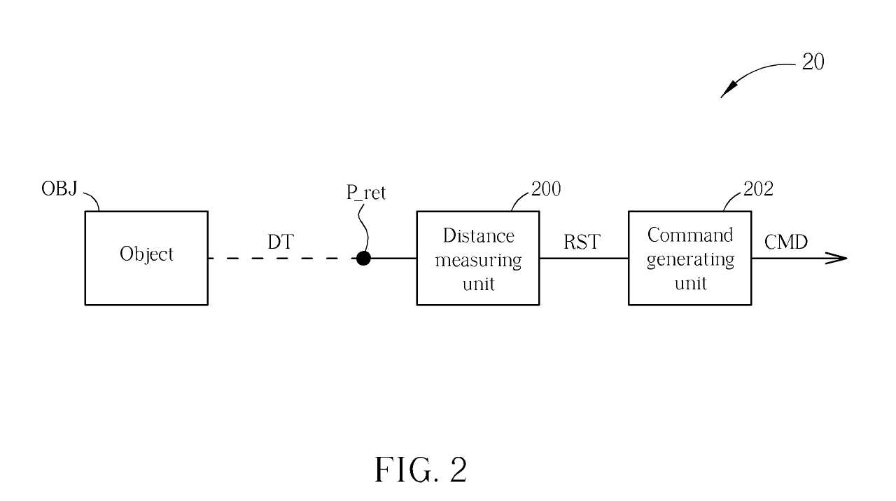

Please refer to FIG. 2, which is a functional block diagram of a control device 20 according to an embodiment of the present invention. The control device 20 is utilized for controlling an electronic device, which can be a common portable electronic device, such as a personal digital assistant (PDA), a smart mobile communication device, a laptop, etc. The control device 20 includes a distance measuring unit 200 and a command generating unit 202. The distance measuring unit 200 can be a common distance sensing element, for detecting a distance DT between an object OBJ and a reference point P_ref, to generate a detection result RST for the command generating unit 202. The command generating unit 202 generates a corresponding control command CMD according to the detection result RST.

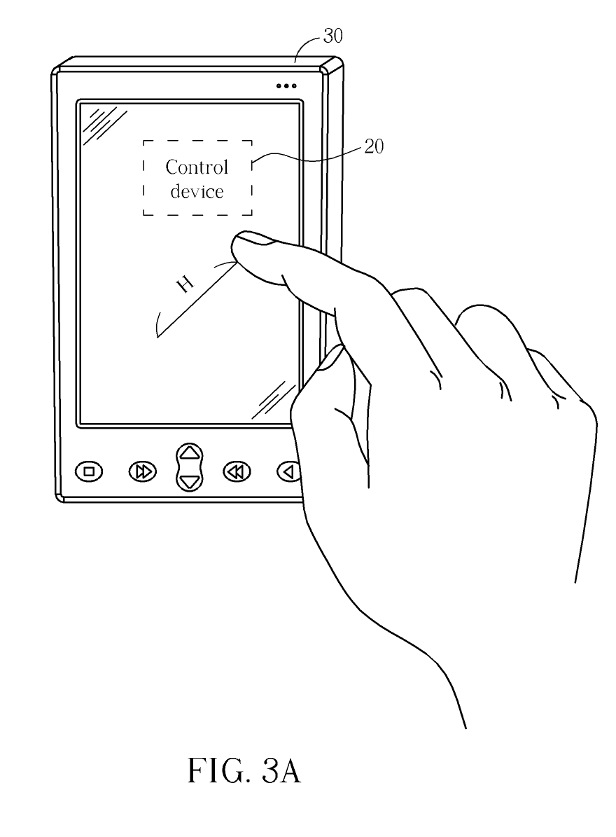

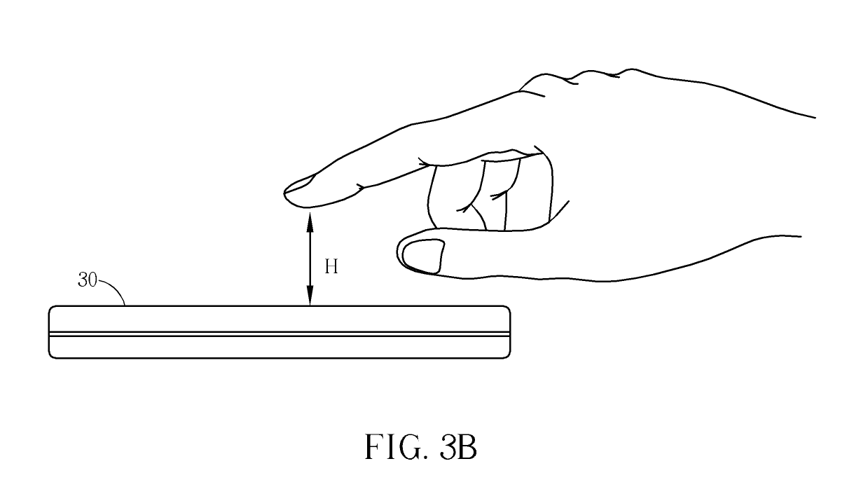

In a word, the control device 20 generates the corresponding control command CMD according to the distance DT between the object OBJ and the reference point P_ref. If the above concept is applied in a portable electronic device, a variety of interesting operating methods can be realized. For example, please refer to FIG. 3A and FIG. 3B, which are a front-view and a lateral-view diagrams of a smart mobile communication device 30 according to an embodiment of the present invention. The smart mobile communication device 30 comprises the control device 20 shown in FIG. 2, which can perform specific operations according to a distance H between an external object (taking a finger FGR for example) and a screen. Noticeably, for simply illustrating the concept of the present invention, a location of the control device 20 relative to the smart mobile communication device 30 is not shown in FIG. 3A and FIG. 3B.

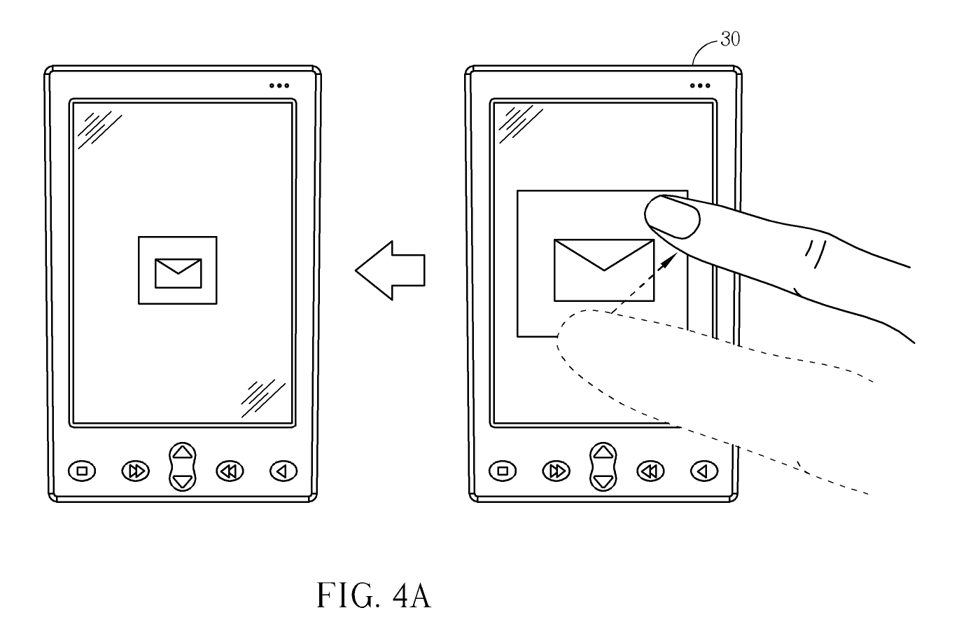

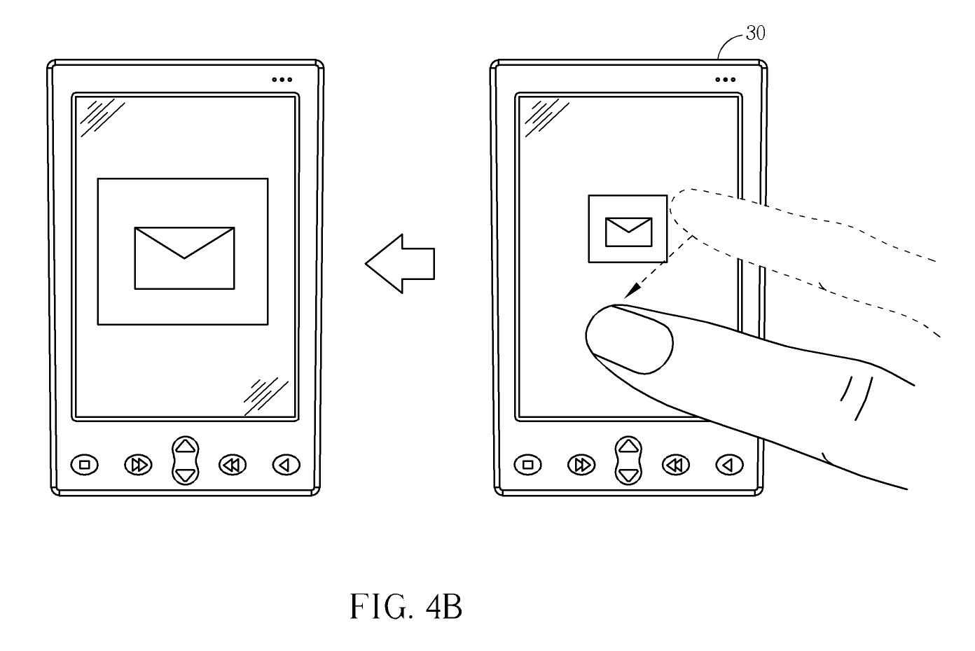

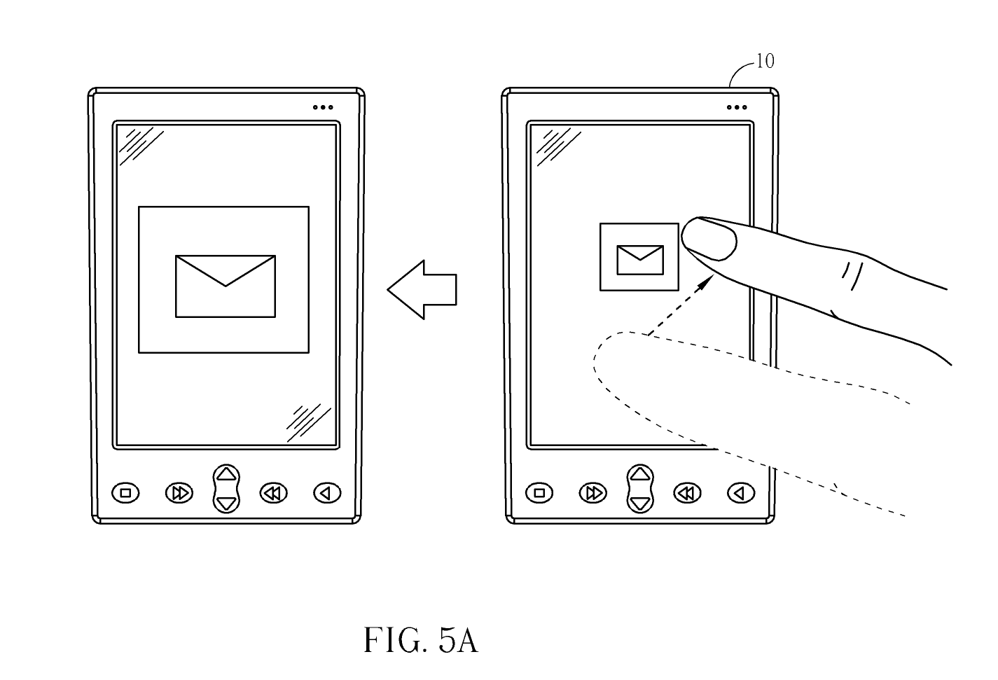

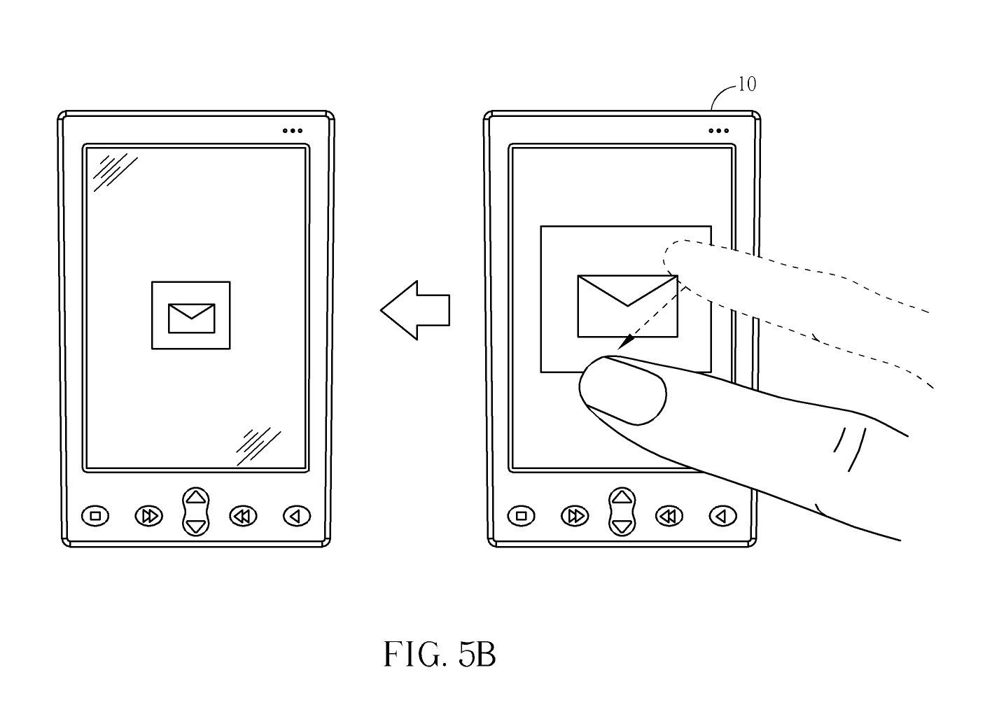

In the smart mobile communication device 30, after the control device 20 detects a variation of the distance H, the smart mobile communication device 30 performs different operations, and even realizes effects similar to the multiple-point touch control according to the control command CMD of the control device 20. In other words, the user only needs to use one finger to approach or leave the screen of the smart mobile communication device 30, while the control effects of the multiple-point touch control can be achieved. For example, according to the command CMD of the control device 20, the smart mobile communication device 30 can magnify a frame or a picture displayed by the screen when the control device 20 detects the finger FGR approaching, as shown in FIG. 4A, and minify the frame or the picture displayed by the screen when the finger FGR is leaving, as shown in FIG. 4B. As a result, using only the finger FGR (or other objects) to approach or leave the screen, the user can adjust a size of the frame or the picture, which realizes the intuitive control, and enhances operating fun. More importantly, for a user incapable of simultaneously clicking multiple points or making big moves due to disabled body or some limited applications, the present invention can provide the control effects of the traditional multiple-point touch control, to enhance convenience.

Noticeably, FIG. 4A and FIG. 4B are utilized for illustrating a possible operating embodiment of the smart mobile communication device 30, in order to illustrate an operation that the present invention controls the smart mobile communication device 30 according to the distance H between the finger FGR and the screen. Alterations retaining the concept belong to the scope of the present invention. For example, in FIG. 5A, the smart mobile communication device 30 minifies the frame or the picture displayed by the screen when the finger FGR is approaching, and in FIG. 5B, the smart mobile communication device 30 magnifies the frame or the picture displayed by the screen when the finger FGR is leaving. Besides, content of the detection result RST can be a distance determination result at each time, or a distance variation within a specific interval.

In addition, in order to avoid the frame displayed by the smart mobile communication device 30 being magnified or minified too frequently, other control conditions can be added as well. For example, when a specific program (e.g. browse program of picture, website, etc.) is started, a specific key or switch is switched on, or a graphical user interface is selected, the function of the control device 20 is activated.

Moreover, other than controlling the size of the displayed frame according to the distance between the finger FGR and the screen, the smart mobile communication device 30 can control statuses such as volume, screen bright, contrast, etc., or can be added other elements to achieve special effects as well. For example, a light emitting element can be added on a housing of the smart mobile communication device 30, and emits light when the finger FGR is approaching, and dims or emits light with a different color when the finger FGR is leaving.

On the other hand, when realizing the control device 20, the distance measuring unit 200 and the command generating unit 202 shall be properly designed, or the operating logic shall be properly adjusted according to system requirements. Take FIG. 2 for example, the designer can set that when the distance DT between the object OBJ and the reference point P_ref is smaller than a specific value, the distance measuring unit 200 starts to detect or report the detection result RST, for saving system resources. In addition, the detection result RST outputted by the distance measuring unit 200 can be a value of the distance DT (such as 5.6 cm, 3 inch, etc.), or can be expressed by analog information, such as voltage, current, or digital information, such as binary value, hexadecimal value etc. Meanwhile, the realization of the distance measuring unit 200 is not limited to any specific technique. For example, when an infrared sensing method is applied, the distance measuring unit 200 senses thermal energy of the object OBJ from the reference point P_ref, so as to determine the distance DT. When an electromagnetic sensing method is applied, the distance measuring unit 200 senses electromagnetic energy or electromagnetic effects of the object OBJ from the reference point P_ref, so as to determine the distance DT. When an ultrasonic sensing method is applied, the electronic device shall emit an ultrasonic signal to the object OBJ, such that the distance measuring unit 200 receives signals reflected by the object OBJ at the reference point P_ref, to determine the distance DT. When an optical sensing method is applied, the distance measuring unit 200 senses optical reflection or optical waves of the object OBJ from the reference point P_ref, to determine the distance DT. However, to determine the distance DT is only a skill used in the present invention, and shall not limit the invention scope.

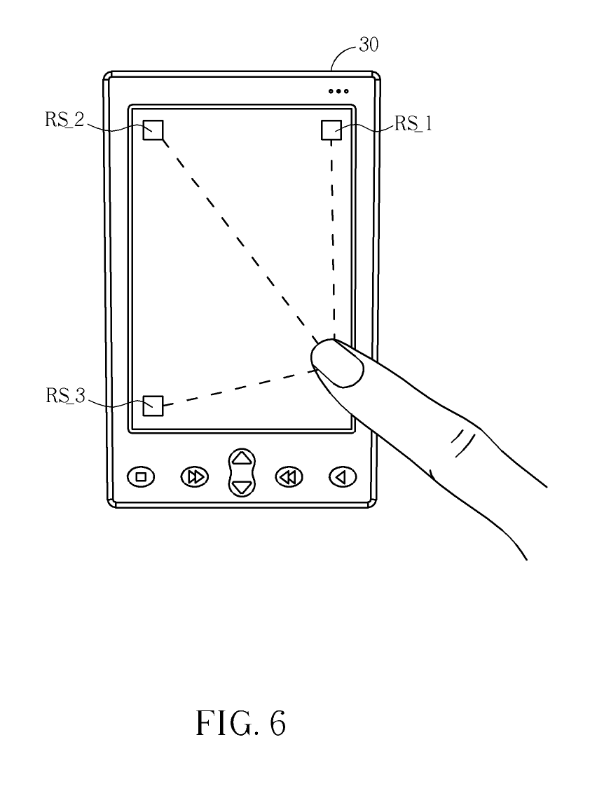

In the above, the reference point P_ref is a point of the electronic device, and those skilled in the art can adjust the position of the reference point P_ref or add other reference points according to system requirements when realizing the distance measuring unit 200. For example, in FIG. 6, the smart mobile communication device 30 utilizes detectors RS_1, RS_2, RS_3 in three corners of the screen, to detect distances between the detectors RS_1, RS_2, RS_3 and a finger, so as to determine a distance between the screen and the finger by positioning the finger from the detectors RS_1, RS_2, RS_3.

In addition, when the distance measuring unit 200 is applied, operating processes shall be properly designed according to elements of the corresponding electronic device. For example, in a display device, the distance measuring unit 200 can be designed to increase definition of the display device when a user is approaching, and reduce definition of the display device when the user is leaving. In a navigation device, the distance measuring unit 200 can be designed to display a detailed map (with reduced scale) when a finger is approaching, and display an outline map (with increased scale) when the finger is leaving.

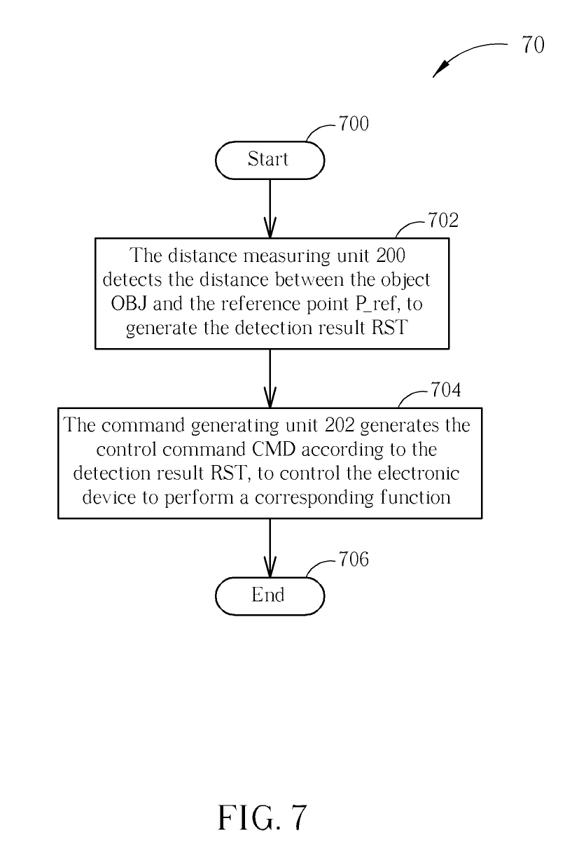

Therefore, via the control device 20, the present invention can provide intuitive control, and enhance operating fun. More importantly, for disabled users or some limited applications, the present invention can provide multiple-point touch control effects, to enhance convenience. Operations of the control device 20 can be summarized into a control process 70, as shown in FIG. 7. The control process 70 includes the following steps:

Step 700: Start.

Step 702: The distance measuring unit 200 detects the distance between the object OBJ and the reference point P_ref, to generate the detection result RST.

Step 704: The command generating unit 202 generates the control command CMD according to the detection result RST, to control the electronic device to perform a corresponding function.

Step 706: End.

Detailed description of the control process 70 can be referred to the above, and is not narrated hereinafter for simplicity.

To sum up, the present invention detects a distance between an external object and a reference point of an electronic device, and controls functions of the electronic device accordingly, which can provide intuitive control, operating fun, and significantly enhance convenience for disabled users or some limited applications.

Those skilled in the art will readily observe that numerous modifications and alterations of the device and method may be made while retaining the teachings of the invention.

What is claimed is:

1. A control method for an electronic device comprising:
detecting a distance between an object and a reference point of the electronic device; and
generating a control command for the electronic device according to the distance between the object and the reference point, to control the electronic device to perform a corresponding function.

2. The control method of claim 1, wherein the step of detecting the distance between the object and the reference point of the electronic device is starting to detect the distance between the object and the reference point of the electronic device when the distance between the object and the reference point is smaller than a predefined value.

3. The control method of claim 1, wherein the step of detecting the distance between the object and the reference point of the electronic device is starting to detect the distance between the object and the reference point of the electronic device when a switch of the electronic device is triggered.

4. The control method of claim 1, wherein the step of detecting the distance between the object and the reference point of the electronic device is utilizing an infrared sensing method, for sensing thermal energy of the object from the reference point, to detect the distance between the object and the reference point of the electronic device.

5. The control method of claim 1, wherein the step of detecting the distance between the object and the reference point of the electronic device is utilizing an ultrasonic sensing method, for emitting an ultrasonic signal from the electronic device to the object, and receiving a signal reflected by the object at the reference point, to detect the distance between the object and the reference point of the electronic device.

6. The control method of claim 1, wherein the step of detecting the distance between the object and the reference point of the electronic device is utilizing an electromagnetic sensing method, for sensing electromagnetic energy of the object from the reference point, to detect the distance between the object and the reference point of the electronic device.

7. The control method of claim 1, wherein the step of detecting the distance between the object and the reference point of the electronic device is utilizing an optical sensing method, for sensing optical reflection or optical waves of the object from the reference point, to detect the distance between the object and the reference point of the electronic device.

8. The control method of claim 1, wherein the electronic device comprises a screen, and the control command is utilized for controlling a size of a picture displayed by the screen.

9. The control method of claim 8, wherein the control command is utilized for magnifying the picture when the distance between the object and the reference point is greater than a predefined value, and minifying the picture when the distance between the object and the reference point is smaller than the predefined value.

10. The control method of claim 8, wherein the control command is utilized for minifying the picture when the distance between the object and the reference point is greater than a predefined value, and magnifying the picture when the distance between the object and the reference point is smaller than the predefined value.

11. The control method of claim 8, wherein the control command is utilized for minifying the picture when a variation of the distance between the object and the reference point is greater than a predefined value, and magnifying the picture when the variation of the distance between the object and the reference point is smaller than the predefined value.

12. The control method of claim 8, wherein the control command is utilized for magnifying the picture when a variation of the distance between the object and the reference point is greater than a predefined value, and minifying the picture when the variation of the distance between the object and the reference point is smaller than the predefined value.

13. A control device for an electronic device comprising:
a distance measuring unit, for detecting a distance between an object and a reference point of the electronic device, to generate a detection result; and
a command generating unit, for generating a control command for the electronic device according to the detection result, to control the electronic device to perform a corresponding function.

14. The control device of claim 13, wherein the distance measuring unit starts to detect the distance between the object and the reference point of the electronic device when the distance between the object and the reference point is smaller than a predefined value.

15. The control device of claim 13, wherein the distance measuring unit starts to detect the distance between the object and the reference point of the electronic device when a variation of the distance between the object and the reference point is greater than a predefined value.

16. The control device of claim 13, wherein the distance measuring unit starts to detect the distance between the object and the reference point of the electronic device when a variation of the distance between the object and the reference point is smaller than a predefined value.

17. The control device of claim 13, wherein the distance measuring unit starts to detect the distance between the object and the reference point of the electronic device when a switch of the electronic device is triggered.

18. The control device of claim 13, wherein the distance measuring unit is an infrared detector, utilizing an infrared sensing method, for sensing thermal energy of the object from the reference point, to detect the distance between the object and the reference point of the electronic device.

19. The control device of claim 13, wherein the electronic device comprises an ultrasonic emitter, for emitting an ultrasonic signal to the object, and the distance measuring unit is an ultrasonic detector, utilizing an ultrasonic sensing method, for receiving a signal reflected by the object at the reference point, to detect the distance between the object and the reference point of the electronic device.

20. The control device of claim 13, wherein the distance measuring unit is an electromagnetic detector, utilizing an electromagnetic sensing method, for sensing electromagnetic energy of the object from the reference point, to detect the distance between the object and the reference point of the electronic device.

21. The control device of claim 13, wherein the distance measuring unit is an optical detector, utilizing an optical sensing method, for sensing optical reflection or optical waves of the object from the reference point, to detect the distance between the object and the reference point of the electronic device.

22. The control device of claim 13, wherein the electronic device comprises a screen, and the command generating unit generates the control command, to control a size of a picture displayed by the screen.

23. The control device of claim 22, wherein the control command generated by the command generating unit is utilized for magnifying the picture when the distance between the object and the reference point is greater than a predefined value, and utilized for minifying the picture when the distance between the object and the reference point is smaller than the predefined value.

24. The control device of claim 22, wherein the control command generated by the command generating unit is utilized for minifying the picture when the distance between the object and the reference point is greater than a predefined value, and utilized for magnifying the picture when the distance between the object and the reference point is smaller than the predefined value.

25. The control device of claim 22, wherein the control command generated by the command generating unit is utilized for magnifying the picture when a variation of the distance between the object and the reference point is greater than a predefined value, and utilized for minifying the picture when the variation of the distance between the object and the reference point is smaller than the predefined value.

26. The control device of claim 22, wherein the control command generated by the command generating unit is utilized for minifying the picture when a variation of the distance between the object and the reference point is greater than a predefined value, and utilized for magnifying the picture when the variation of the distance between the object and the reference point is smaller than the predefined value.

27. An electronic device, capable of enhancing operating efficiency, comprising:
an operating circuit;
a screen; and
a control device, comprising:
a distance measuring unit, for detecting a distance between an object and a reference point of the screen, to generate a detection result; and
a command generating unit, for generating a control command for the operating circuit according to the detection result, to control the operating circuit to perform a corresponding function.

28. The electronic device of claim 27, wherein the distance measuring unit starts to detect the distance between the object and the reference point when the distance between the object and the reference point is smaller than a predefined value.

29. The electronic device of claim 27, wherein the distance measuring unit starts to detect the distance between the object and the reference point when a variation of the distance between the object and the reference point is greater than a predefined value.

30. The electronic device of claim 27, wherein the distance measuring unit starts to detect the distance between the object and the reference point when a variation of the distance between the object and the reference point is smaller than a predefined value.

31. The electronic device of claim 27, wherein the distance measuring unit starts to detect the distance between the object and the reference point when a trigger switch of the electronic device is triggered.

32. The electronic device of claim 27, wherein the distance measuring unit is an infrared detector, utilizing an infrared sensing method, for sensing thermal energy of the object from the reference point, to detect the distance between the object and the reference point.

33. The electronic device of claim 27, wherein the operating circuit comprises an ultrasonic emitter, for emitting an ultrasonic signal to the object, and the distance measuring unit is an ultrasonic detector, utilizing an ultrasonic sensing method, for receiving a signal reflected by the object at the reference point, to detect the distance between the object and the reference point.

34. The electronic device of claim 27, wherein the distance measuring unit is an electromagnetic detector, utilizing an electromagnetic sensing method, for sensing electromagnetic energy of the object from the reference point, to detect the distance between the object and the reference point.

35. The electronic device of claim 27, wherein the distance measuring unit is an optical detector, utilizing an optical sensing method, for sensing optical reflection or optical waves of the object from the reference point, to detect the distance between the object and the reference point.

36. The electronic device of claim 27, wherein the control command generated by the command generating unit is utilized for controlling a size of a picture displayed by the screen.

37. The electronic device of claim 36, wherein the control command generated by the command generating unit is utilized for magnifying the picture when the detection result indicates the distance between the object and the reference point is greater than a predefined value, and utilized for minifying the picture when the detection result indicates the distance between the object and the reference point is smaller than the predefined value.

38. The electronic device of claim 36, wherein the control command generated by the command generating unit is utilized for minifying the picture when the detection result indicates the distance between the object and the reference point is greater than a predefined value, and utilized for magnifying the picture when the detection result indicates the distance between the object and the reference point is smaller than the predefined value.

39. The electronic device of claim 36, wherein the control command generated by the command generating unit is utilized for magnifying the picture when the detection result indicates a variation of the distance between the object and the reference point is greater than a predefined value, and utilized for minifying the picture when the detection result indicates the variation of the distance between the object and the reference point is smaller than the predefined value.

40. The electronic device of claim 36, wherein the control command generated by the command generating unit is utilized for minifying the picture when the detection result indicates a variation of the distance between the object and the reference point is greater than a predefined value, and utilized for magnifying the picture when the detection result indicates the variation of the distance between the object and the reference point is smaller than the predefined value.
